(19) United States
(12) Patent Application Publication
(10) Pub. No.: US 2026/0171967 A1
(43) Pub. Date: Jun. 18, 2026

(54) METHOD FOR COMPENSATING MECHANICAL AND ELECTRICAL NONLINEARITIES OF OSCILLATORS BASED ON MEMS DEVICES AND MEMS SYSTEM THEREOF

(71) Applicants: STMicroelectronics International N.V., Geneva (CH); Politecnico Di Milano, Milano (IT)

(72) Inventors: Gabriele GATTERE, Castronno (Varese) (IT); Giacomo LANGFELDER, Milano (IT); Christian PADOVANI, Massalengo (IT)

(73) Assignee: STMicroelectronics International N.V., Geneva (CH)

(21) Appl. No.: 19/418,870

(22) Filed: Dec. 12, 2025

(30) Foreign Application Priority Data
Dec. 17, 2024 (IT) 102024000028704

(51) Int. Cl. H03B 5/30

(52) U.S. Cl. CPC H03B 5/30

(57) ABSTRACT

A microelectromechanical oscillator includes: a device including a movable structure and oscillating at a working frequency; a sustaining circuit configured to sustain oscillations of the device; a compensation terminal capacitively coupled to the movable structure and configured to apply a compensation signal to the movable structure; and a modulation terminal cooperating with the sustaining circuit to control an amplitude of the oscillations. An electronic processing circuit is configured to: apply a modulation signal to the modulation terminal; generate, in response to an output signal of the oscillator, a read-out signal indicative of a frequency variation with respect to the working frequency; demodulate the read-out signal using the modulation signal, obtaining an error signal indicative of a phase difference between the modulation signal and the read-out signal; and generate the compensation signal by comparing the error signal with a reference signal.

### PRIORITY CLAIM

This application claims the priority benefit of Italian Application for Patent No. 102024000028704 filed on Dec. 17, 2024, the content of which is hereby incorporated by reference in its entirety to the maximum extent allowable by law.

### TECHNICAL FIELD

The present invention relates to a method for compensating mechanical and electrical nonlinearities present in oscillators based on microelectromechanical system (MEMS) devices and a MEMS system thereof.

### BACKGROUND

MEMS oscillators find their main use in timing reference systems, such as, for example, precision watches and high-frequency clocks, or as subsystems within sensors, such as for example gyroscopes, magnetometers, micromirrors, and frequency-modulated accelerometers.

A MEMS oscillator typically comprises a MEMS device, or resonator, having a natural resonance frequency, and a sustaining circuit that is configured to keep the MEMS resonator oscillating around a predefined working point by providing a forcing signal. Ideally, a signal applying a sinusoidal forcing at the resonance frequency generates an oscillating displacement of the MEMS resonator at the same frequency.

In practice, however, due to, for example, thermomechanical stresses and/or particular electrical biasing of the MEMS oscillator, mechanical nonlinearities may be present which may produce a hardening reaction of the MEMS resonator. The hardening reaction is nonlinear with the displacement: in particular, a signal applying s sinusoidal forcing at the resonance frequency may generate a distorted displacement, resulting in a waste of energy towards non-useful frequencies. The spectral response of a MEMS oscillator which has mechanical nonlinearities shows a bending of the resonance peak, typically a hardening bending, i.e., a bending of the peak towards frequencies higher than the resonance frequency.

In capacitive MEMS resonators, and in particular in those which comprise parallel plate electrodes biased to predetermined voltages, electrical nonlinearities induced by electrostatic forces may also occur: the distortion caused by this type of nonlinearities tends to bend the resonance peak of the MEMS oscillator spectral response towards frequencies lower than the resonance frequency, i.e., it tends to create a softening bending.

In general, in the presence of nonlinearities, a MEMS oscillator produces at output an oscillating signal at a frequency that differs from the natural resonance frequency of the MEMS resonator by a frequency variation.

The performance of MEMS oscillators in terms of noise, especially phase noise, is strictly correlated to the maximum amplitude of the displacement of the MEMS resonator and to its nonlinearities.

Generally, despite the design efforts, the two nonlinear contributions highlighted above, although having opposite signs, may be different from each other in modulus and therefore may not compensate each other. Furthermore, increasing the amplitude of the sinusoidal forcing to increase the MEMS resonator displacement, although being advantageous to minimize the phase noise of the MEMS oscillator, may lead to even more accentuated nonlinearities, comprising bi-stability and hysteresis phenomena, and therefore to an overall worsening of the performance.

To try to compensate for the effects of electrical and mechanical nonlinearities, there are currently used solutions such as: an open-loop regulation of voltages and displacement until a condition is met in which the electrical and mechanical nonlinearities are equal and opposite; or the search for the maximum displacement before the triggering of bi-stability conditions; or, again, the use of linear comb transducers combined with the minimization of mechanical nonlinearities by adopting specific spring configurations specifically designed to minimize mechanical nonlinearities. However, the known solutions are not entirely satisfactory and may not lead to a complete elimination of mechanical and electrical nonlinearities.

There is accordingly a need in the art to overcome or at least in part mitigate the disadvantages and limitations of the state of the art.

### SUMMARY

In an embodiment, a microelectromechanical system comprises a microelectromechanical oscillator and an electronic processing circuit. The microelectromechanical oscillator includes: a microelectromechanical device, comprising a movable structure and oscillating at a working frequency; a sustaining circuit configured to sustain oscillations of the microelectromechanical device; a compensation terminal capacitively coupled to the movable structure and configured to apply a compensation signal to the movable structure; and a modulation terminal cooperating with the sustaining circuit to control an amplitude of the oscillations of the microelectromechanical device. The electronic processing circuit is configured to: apply, to the modulation terminal, a modulation signal having a modulation frequency; generate, in response to an output signal of the microelectromechanical oscillator, a read-out signal indicative of a frequency variation of the oscillations of the microelectromechanical device with respect to the working frequency; demodulate, in a synchronous manner, the read-out signal using the modulation signal, so as to obtain an error signal indicative of a phase difference between the modulation signal and the read-out signal; compare the error signal with a reference signal; and generate the compensation signal from the comparison.

In an embodiment, a method is presented for compensating nonlinearities of a microelectromechanical oscillator. The microelectromechanical oscillator comprises: a microelectromechanical device comprising a movable structure and oscillating at a working frequency; a sustaining circuit configured to sustain oscillations of the microelectromechanical device; a compensation terminal capacitively coupled to the movable structure and configured to apply a compensation signal to the movable structure; and a modulation terminal cooperating with the sustaining circuit to control an amplitude of the oscillations of the microelectromechanical device. The method comprises: applying to the modulation terminal a modulation signal having a modulation frequency; generating, in response to an output signal of the microelectromechanical oscillator, a read-out signal indicative of a frequency variation of the oscillations of the microelectromechanical device with respect to the working frequency; demodulating, in a synchronous manner, the read-out signal using the modulation signal, so as to obtain an error signal indicative of a phase difference between the modulation signal and the read-out signal; comparing the error signal with a reference signal; and generating the compensation signal from the comparison.

### BRIEF DESCRIPTION OF THE DRAWINGS

For a better understanding of the present invention, preferred embodiments are presented, by way of non-limiting example, with reference to the attached drawings, wherein:

FIG. 1 is a simplified block diagram of a nonlinearity compensation system;

FIG. 2 shows time and frequency diagrams corresponding to three distinct nonlinearity sensing conditions of the compensation system of FIG. 1;

FIG. 3 is a simplified block diagram of a nonlinearity compensation system; and

FIG. 4 is a simplified block diagram of a nonlinearity compensation system.

### DETAILED DESCRIPTION

The following description refers to the arrangement shown in the drawings; consequently, expressions such as “above”, “below”, “upper”, “lower”, “top”, “bottom”, “right”, “left” and the like relate to the accompanying Figures and are not to be construed as limiting.

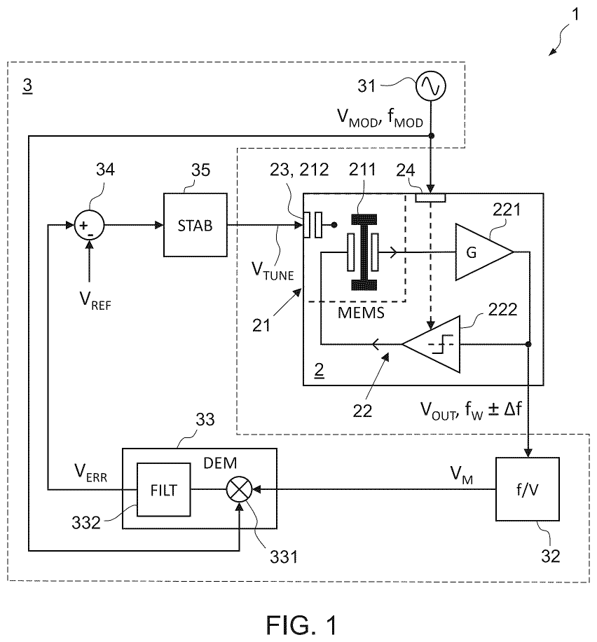

FIG. 1 shows a microelectromechanical system (or simply “system”) to compensate nonlinearities of oscillators based on microelectromechanical system (MEMS) devices according to one embodiment, indicated as a whole by the numeral 1 and comprising a MEMS oscillator 2 and an electronic processing circuit 3.

The oscillator 2 comprises in detail a MEMS device, or resonator, 21 and a sustaining circuit 22 coupled to the resonator 21. The resonator 21 comprises a movable microelectromechanical structure 211, or simply movable structure, which has a resonance mode along an axis of the movable structure 211 at a natural resonance frequency f_{RES}. The sustaining circuit 22 is configured to keep the movable structure 211 of the resonator 21, and more generally the resonator 21, in oscillation around a predefined working point. The axis along which the sustaining circuit 22 keeps the resonator 21 in oscillation is also called the driving axis.

For example, the resonator 21 is a capacitive resonator which comprises therewithin a parallel plate and/or an interdigitated fixed and movable electrodes arrangement of driving electrodes, for a capacitive actuation of the movable structure 211. For example, the resonator 21 has, in a non-limiting manner, a movable structure of the double-ended tuning fork type and the oscillator 2 is the sensitive element of a frequency-modulated accelerometer. In general, the oscillator 2, and therefore the system 1, may be part of a frequency-modulated sensor, wherein the movable structure 211 of the resonator 21 comprises one or more movable masses capable of oscillating along the driving axis and of sensing a physical quantity (e.g., an angular velocity in the case of a gyroscope) starting from oscillations along an axis perpendicular to the driving axis. Alternatively, the oscillator 2 may be part of a timing device or system configured to produce a timing output (e.g., a clock) at the natural resonance frequency.

The oscillator 2, and more in particular the resonator 21, is further provided with a compensation terminal 23 configured to apply a compensation signal V_{TUNE} to the movable structure 211. Furthermore, the compensation terminal 23 is capacitively coupled to the movable structure 211. In detail, the compensation terminal 23 is internally connected to a compensation electrode 212 of the resonator 21, on which it sets a compensation bias voltage. In more detail, the compensation electrode 212 is capacitively coupled to the movable structure 211 or to dedicated electrodes forming part of the same. For example, the compensation electrode 212 and the movable structure 211, or dedicated electrodes thereof, are in a parallel plate configuration, wherein the compensation electrode 212 is a fixed electrode of the resonator 21. In alternative embodiments, the compensation terminal 23 may be connected to driving electrodes of the movable structure 211; or, the compensation terminal 23 may be connected to sensing electrodes of the resonator 21, if the oscillator 2 were integrated into a sensor.

As explained in more detail below, the compensation terminal 23, and more in particular the compensation electrode 212, are used in the oscillator 2 in order to create a regulation of the electrostatic forces acting on the movable structure 211, and more generally on the resonator 21, modifying the electrostatic softening of the resonator 21 and, therefore, the oscillation condition of the oscillator 2.

In addition to the electrode arrangements described above, the resonator 21 may also comprise bias terminals and electrodes for its internal structures, not shown in the attached Figures, according to bias architectures known in the art.

The sustaining circuit 22 defines, together with the resonator 21, an oscillation loop of the oscillator 2. In particular, the resonator 21 functions as a frequency-selective element of this oscillation loop, while the sustaining circuit 22 comprises elements which allow the Barkhausen stability criterion to be met, i.e., to keep the oscillation stable. More in particular, the sustaining circuit 22 comprises a gain circuit stage 221 and a limitation circuit stage 222 for controlling the oscillation amplitude at a constant and predefined value. The oscillation amplitude in the oscillator 2 in fact defines the maximum displacement to which the movable structure 211 of the resonator 21 is subject around the predefined working point. In practice, in conditions of absence of nonlinearities of the oscillator 2, the oscillation of the oscillation loop is a signal which oscillates at a working frequency f_{W}. The working frequency f_{W} of the resonator 21, and therefore of the oscillator 2, is for example proximate or equal to the natural resonance frequency f_{RES} of the movable structure 211. In other words, in the oscillation condition in which the oscillation frequency is the working frequency f_{W}, the movable structure 211 exhibits linear behavior.

In a non-limiting embodiment, the gain circuit stage 221 comprises one or more amplification elements, whose gain values are controlled, for example, by an Automatic Gain Control (AGC) configuration. The limitation circuit stage 222 comprises, for example, a limiting element and/or a comparator element, or more generally an element capable of limiting the amplitude of the oscillation between a predefined lower saturation value and a predefined upper saturation value.

The oscillator 2 further comprises a modulation terminal 24 of the sustaining circuit 22. In detail, the modulation terminal 24 is used in the system 1 in order to modulate the oscillation amplitude in the oscillator 2, as explained in more detail below. In a non-limiting embodiment, such as that shown in FIG. 1, the modulation terminal 24 is internally connected to the limitation circuit stage 222 of the sustaining circuit 22.

The electronic processing circuit 3, for example an ASIC, is coupled to the oscillator 2. In detail, the electronic processing circuit 3 comprises a signal generator 31, a read-out circuit stage 32, a demodulator 33, a comparator 34, and a stabilizer circuit stage 35. According to one aspect of the present invention, the electronic processing circuit 3 implements a closed-loop compensation function of the mechanical and electrical nonlinearities from which the oscillator 2 may suffer.

The signal generator 31 is configured to generate and apply to the modulation terminal 24 of the oscillator 2 a modulation signal V_{MOD}. In detail, the modulation signal V_{MOD} is a signal oscillating at a modulation frequency f_{MOD}. Even more in detail, the modulation signal V_{MOD} is a sinusoidal signal. As anticipated, the modulation signal V_{MOD} is used to modulate the oscillation amplitude of the oscillation loop in the oscillator 2. For example, the amplitude modulation is provided by modifying, based on the modulation signal V_{MOD}, the lower saturation value and the upper saturation value of the limitation circuit stage 222.

The modulation frequency f_{MOD} of the modulation signal V_{MOD} is selected so as not to alter the working frequency f_{W} of the oscillator 2. At the same time, the modulation frequency f_{MOD} is selected so as to be compatible with the band parameters of the gain control implemented by the gain circuit stage 221. Furthermore, if the oscillator 2 is part of a sensor, the modulation frequency f_{MOD} is selected so as to avoid interferences with a measurement band. For example, if the working frequency f_{W} of the oscillator 2 is of the order of units or tens of kiloHertz, the modulation frequency f_{MOD} is selected in the order of tens or hundreds of Hertz; for example, the modulation frequency f_{MOD} is comprised between 0.1 Hz and 500 Hz, preferably between 1 Hz and 50 Hz.

The maximum amplitude of the modulation signal V_{MOD} is also selected so as not to interfere with the oscillation of the oscillation loop. In other words, the amplitude modulation actuated by the modulation signal V_{MOD} is a small-signal modulation around the predefined working point of the movable structure 211 of the resonator 21.

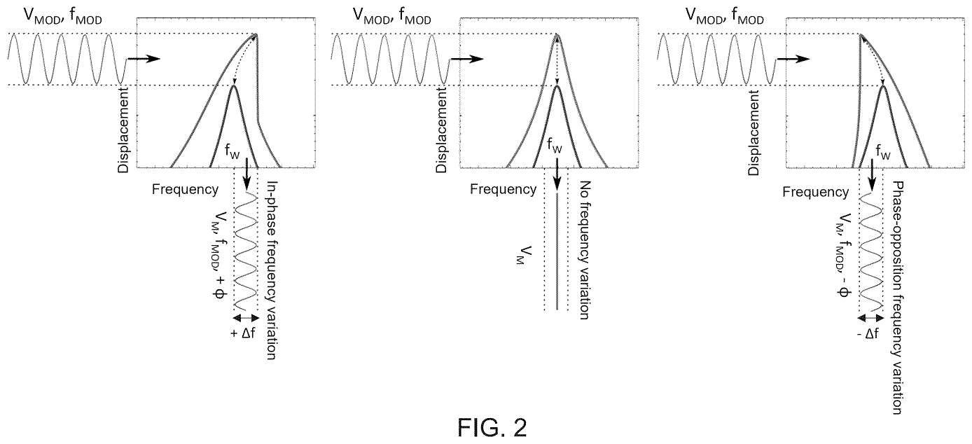

In the presence of nonlinearities of the oscillator 2, the amplitude modulation imparted by the modulation signal V_{MOD} allows to sense a frequency variation Δf of the oscillation of the oscillation loop, i.e., a variation with respect to the working frequency f_{W} of the oscillator 2. In particular, as shown in FIG. 2: if the working frequency f_{W} varies with the same phase as the modulation signal V_{MOD}, the oscillator 2 is subject to a nonlinearity of hardening type; if the working frequency f_{W} varies in phase opposition with respect to the modulation signal V_{MOD}, the oscillator 2 is subject to a nonlinearity of softening type. In the absence of nonlinearities of the oscillator 2, the working frequency f_{W} coincides, for example, with the natural resonance frequency f_{RES} of the resonator 21; such a situation occurs for example when the hardening nonlinear effects already compensate for the softening ones in the oscillator 2. The application of the modulation signal V_{MOD} in the system 1 therefore allows the presence of nonlinearities in the oscillator 2 to be sensed.

In more detail, an output signal V_{OUT} of the oscillator 2, in the presence of nonlinearities, oscillates at a working frequency f_{W}—for example equal to the natural resonance frequency f_{RES} of the resonator 21—varied by an amount equal to the frequency variation Δf. A nonlinearity of hardening type increases the working frequency f_{W} by an amount equal to the frequency variation Δf, while a nonlinearity of softening type decreases the working frequency f_{W} by an amount equal to the frequency variation Δf. More generally, the spectrum of the resonator 21, in nonlinearity conditions, has a bending with respect to the spectrum in linearity conditions, so that the frequency coordinate of the oscillation of the output signal V_{OUT} of the oscillator 2 is shifted, with respect to the natural resonance, with a positive or negative sign by an amount equal to Δf.

With reference again to FIG. 1, the read-out circuit stage 32 is configured to receive the output signal V_{OUT} of the oscillator 2 and to generate, based on the sensing of the output signal V_{OUT}, a read-out signal V_{M} indicative of the frequency variation Δf of the working frequency f_{W} of the oscillator 2. In detail, the read-out signal V_{M} is proportional to the frequency variation Δf. In even more detail, the value of the read-out signal V_{M} is amplitude-shifted in a manner proportional to the frequency variation Δf. Furthermore, the read-out signal V_{M} oscillates at the modulation frequency f_{MOD}. Finally, the read-out signal V_{M} has a relative phase ±φ, with respect to the modulation signal V_{MOD}, which depends, as previously mentioned, on the type of nonlinearity. The read-out circuit stage 32 therefore allows to convert a frequency variation at its input into a corresponding voltage variation at its output.

The demodulator 33 is configured to receive the read-out signal V_{M} and to demodulate it so as to obtain an error signal V_{ERR} indicative of a phase difference between the modulation signal V_{MOD} and the read-out signal V_{M}. In detail, the read-out signal V_{M} is demodulated in a synchronous manner using the same modulation signal V_{MOD}. Furthermore, the error signal V_{ERR} output from the demodulator 33 is a continuous voltage (DC) signal. In more detail, the error signal V_{ERR} is a pseudo-DC signal, as it is constant once a closed-loop steady-state condition is reached, while it varies in a closed-loop transient condition.

The demodulator 33 comprises in detail a multiplier 331 and a filtering circuit stage 332. The multiplier 331 has a first input receiving the read-out signal V_{M} and a second input receiving the modulation signal V_{MOD} generated by the signal generator 31. The filtering circuit stage 332 receives the result of the multiplication between the read-out signal V_{M} and the modulation signal V_{MOD} and filters it, bringing it to baseband, to generate the error signal V_{ERR}. The filtering circuit stage 332 in fact comprises at least one low-pass filter which eliminates the harmonics of the modulation frequency f_{MOD} resulting from the multiplication between the read-out signal V_{M} and the modulation signal V_{MOD}.

The comparator 34 is configured to compare the error signal V_{ERR} with a reference signal V_{REF}, obtaining a compensation signal V_{TUNE}. The reference signal V_{REF} has, for example, a value equal to a value of half the admissible dynamics for the compensation signal V_{TUNE}; for example, the reference signal V_{REF} has a value equal to zero. In detail, the error signal V_{ERR} is received at a positive input of the comparator 34, while the reference signal V_{REF} is received at a negative input of the comparator 34. In this manner, the closed-loop implemented by the electronic processing circuit 3 always operates by minimizing the error.

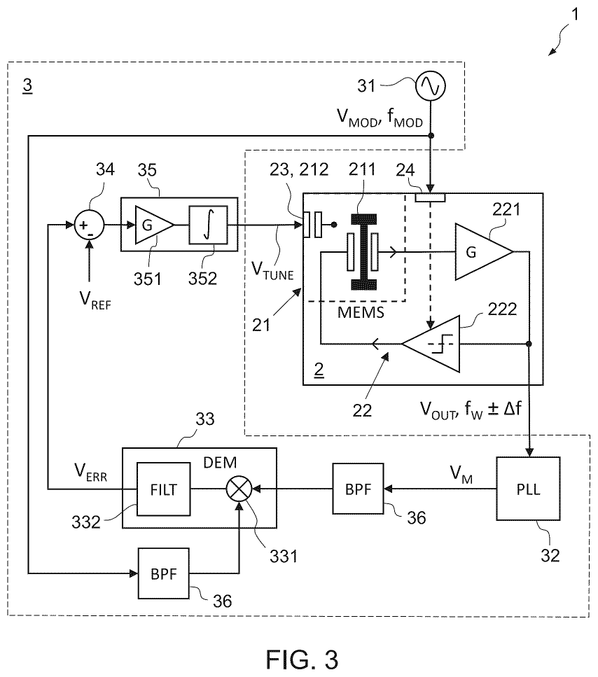

Finally, the compensation signal V_{TUNE} is processed by the stabilizer circuit stage 35, which comprises for example (as shown in the embodiment of FIG. 3) a gain element 351 and an integrator element 352. The compensation signal V_{TUNE} output from the comparator 34 is therefore amplified, to bring it to predefined voltage levels, and integrated in order to stabilize it without static errors. The stabilizer circuit stage 35 is therefore an integrative gain circuit stage. In one embodiment not shown, the gain element 351 and the integrator element 352 are reversed from each other.

The compensation signal V_{TUNE} is then applied to the compensation terminal 23 of the resonator 21, closing the loop, so as to set a compensation bias voltage on the compensation electrode 212 of the resonator 21. As anticipated, the application of the compensation signal V_{TUNE} modifies the oscillation condition of the oscillator 2, bringing its oscillation frequency back to a frequency as close as possible to the working frequency f_{W}, for example to an oscillation frequency proximate to the natural resonance frequency f_{RES} of the resonator 21. That is, the closed-loop compensation allows to nearly cancel the frequency variation Δf, bringing the oscillator 2 back to operating in an oscillation condition which maximizes its energy and performance.

Therefore, according to what has been previously described, the electronic processing circuit 3 implements a feedback control of the working frequency f_{W} of the oscillator 2, with a target value set to an oscillation frequency that is, for example, proximate to the natural resonance frequency f_{RES} of the resonator 21. In detail, the compensation signal V_{TUNE} modifies the electrostatic softening of the resonator 21 in a negative feedback scheme, based on a phase error between the modulation signal V_{MOD} and the output signal V_{OUT} of the oscillator 2. In practice, in fact, the compensation signal V_{TUNE} changes over time, i.e., adapts, automatically based on the frequency variation Δf read, compensating, ultimately, for the nonlinearities present in the oscillator 2. In other words, the automatic and real-time regulation of the electrostatic forces in the resonator 21 allows to impose that the effects of the electrical nonlinearities are equal and opposite to the effects of the mechanical nonlinearities, obtaining accurate compensation. In more detail, the closed-loop control brings the oscillator 2 in an oscillation condition in which the effects of the overall nonlinearities are cancelled, such oscillation condition having a working frequency f_{W} which may not even coincide with the natural resonance frequency f_{RES} of the resonator 21.

The nonlinearity compensation function is generally activable by activating the signal generator 31 of the electronic processing circuit 3. In particular, this function may always remain active during the operation of the oscillator 2, even in a sensing condition of a sensor of which the oscillator 2 is possibly part.

Ultimately, the microelectromechanical system for compensating nonlinearities allows a significant increase in the admissible displacement range for the MEMS resonator, with resulting benefits in terms of phase noise performance of the oscillator. The system also allows for greater stability of the predefined oscillation working point, regardless of the environmental and aging variations to which the oscillator is subject, by virtue of a real-time elimination of the overall nonlinearities.

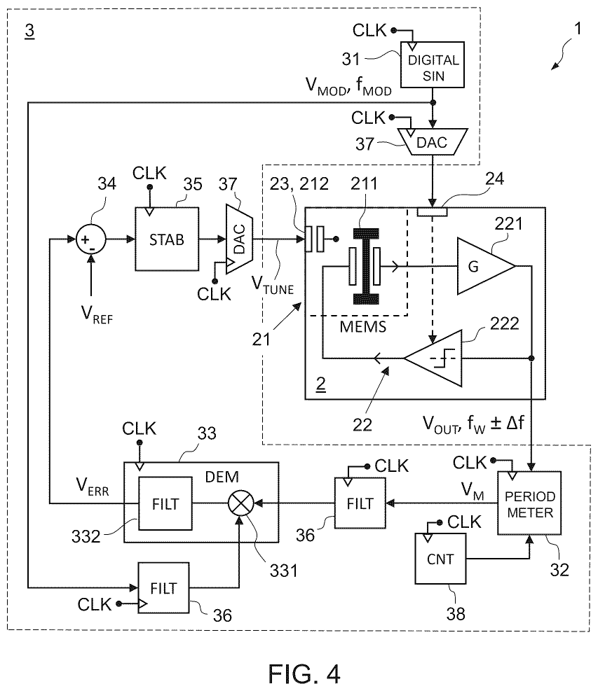

The closed-loop scheme of the system 1 of FIG. 1 may be implemented by an analog solution (diagram of FIG. 3) or by a digital solution (diagram of FIG. 4).

In the diagram in FIG. 3, the read-out circuit stage 32 is implemented by a Phase-Locked Loop (PLL) circuit whose input, or reference, is the output signal V_{OUT} of the oscillator 2 and whose voltage of the regulation node is proportional to the frequency variation Δf. In particular, the input of the respective Voltage-Controlled Oscillator (VCO), i.e., the read-out signal V_{M}, has a value that is amplitude-shifted in a manner proportional to the frequency variation Δf of the working frequency f_{W}. In the diagram of FIG. 3, therefore, the output of the read-out circuit stage 32 is taken at the input of the respective VCO.

With reference again to FIG. 3, a closed-loop control frequency band according to the design preferences, and more generally improved frequency performance of the system 1, may be obtained by using further filtering circuit stages 36. In particular, the further filtering circuit stages 36 each comprise a band-pass filter (BPF) for the read-out signal V_{M} and the modulation signal V_{MOD}, respectively, upstream of the multiplier 331 of the demodulator 33. Alternatively, or in addition, the filtering circuit stage 332 of the demodulator 33 may comprise a filter of the “notch” type, upstream of the low-pass filter, to attenuate the harmonics of the modulation frequency f_{MOD}, so that the following low-pass filter may be implemented with a higher cut-off frequency and ultimately obtain a greater closed-loop frequency band.

In the diagram of FIG. 4, all circuit stages of the electronic processing circuit 3 are implemented by corresponding digital circuit modules. In particular, each digital circuit module has a synchronization input CLK connected to a clock generator, for example external to the electronic processing circuit 3 (and not shown in the Figures). More in particular, the modulation signal V_{MOD} is generated in the digital domain by a digital sinusoid generator which functions as a signal generator 31 and is applied to the modulation terminal 24 of the oscillator 2 after conversion into analog, by a digital-to-analog converter (DAC) 37, and possible filtering by a low-pass filter (not shown). Digital filtering circuit stages 36 corresponding to the filtering circuit stages of FIG. 3 may be present upstream of the digital demodulation and each comprise, for example, a high-pass filter followed by a low-pass filter. The stabilizer circuit stage 35 may comprise, for example, digital correspondents of the gain element 351 and the integrator element 352 of FIG. 3. A further digital-to-analog converter 37 converts the compensation signal V_{TUNE} into analog before it is supplied to the compensation terminal 23 of the resonator 21.

In the diagram of FIG. 4, sensing the output signal V_{OUT} of the oscillator 2 is also performed in the digital domain and, in particular, the read-out circuit stage 32 is implemented by a period meter circuit. More in particular, the period meter circuit 32, by means of a counter 38 to which it is coupled, is configured to count how many clock periods are contained in a period of the output signal V_{OUT} and to provide at output a digital word proportional to the frequency variation Δf of the working frequency f_{W}.

Finally, it is clear that modifications and variations may be made to what has been described and illustrated here without thereby departing from the scope of the present invention, as defined in the attached claims.

For example, some circuit stages of the system may be implemented by analog circuit modules while other circuit stages may be implemented by digital circuit modules.

Furthermore, the circuit stages of the electronic processing circuit 3 may be implemented in a different manner with respect to what has been described and shown, while still performing the same respective tasks. For example, the circuit stages of the electronic processing circuit 3 may be circuit stages belonging to distinct processing circuits and/or which are remote from each other.

1. A microelectromechanical system, comprising:
a microelectromechanical oscillator including:
a microelectromechanical device comprising a movable structure and oscillating at a working frequency;
a sustaining circuit configured to sustain oscillations of the device;
a compensation terminal capacitively coupled to the movable structure and configured to apply a compensation signal to the movable structure; and
a modulation terminal cooperating with the sustaining circuit to control an amplitude of the oscillations of the microelectromechanical device; and
an electronic processing circuit configured to:
apply a modulation signal having a modulation frequency to the modulation terminal;
generate, in response to an output signal of the microelectromechanical oscillator, a read-out signal indicative of a frequency variation of the oscillations of the microelectromechanical device with respect to the working frequency;
demodulate, in a synchronous manner, the read-out signal using the modulation signal, so as to obtain an error signal indicative of a phase difference between the modulation signal and the read-out signal;
compare the error signal with a reference signal; and
generate the compensation signal from the comparison.

2. The system according to claim 1, wherein the modulation signal is a sinusoidal signal and wherein the sustaining circuit comprises a limitation circuit configured to limit the amplitude of the oscillations and wherein the modulation terminal is connected to the limitation circuit.

3. The system according to claim 1, wherein the read-out signal is proportional to the frequency variation of the oscillations of the microelectromechanical device with respect to the working frequency.

4. The system according to claim 1, wherein a value of the read-out signal is amplitude-shifted proportionally to the frequency variation, and wherein the read-out signal oscillates at the modulation frequency.

5. The system according to claim 1, wherein the compensation terminal is connected to a compensation electrode of the microelectromechanical device, the compensation electrode being capacitively coupled to electrodes of the movable structure.

6. The system according to claim 5, wherein the electrodes of the movable structure are in a parallel plate configuration.

7. The system according to claim 1, wherein the electronic processing circuit comprises a phase-locked loop circuit configured to generate the read-out signal from the output signal of the microelectromechanical oscillator.

8. The system according to claim 1, wherein the electronic processing circuit comprises a digital period meter and a digital counter configured to generate the read-out signal from the output signal of the microelectromechanical oscillator.

9. The system according to claim 1, wherein the error signal and the reference signal are continuous voltage signals, and wherein the reference signal has a value equal to a value of half the admissible dynamics for the compensation signal.

10. The system according to claim 1, wherein the electronic processing circuit comprises a demodulator configured to demodulate the read-out signal, the demodulator comprising a multiplier and a filtering circuit stage, in sequence to the multiplier, the filtering circuit stage comprising a low-pass filter and/or a notch filter.

11. The system according to claim 1, wherein the electronic processing circuit further comprises, upstream of the multiplier, a band-pass filter for each of the read-out signal and the modulation signal.

12. The system according to claim 1, wherein the working frequency of the microelectromechanical device is substantially equal to a natural resonance frequency of the movable structure.

13. A method for compensating nonlinearities of a microelectromechanical oscillator that comprises: a microelectromechanical device comprising a movable structure and oscillating at a working frequency; a sustaining circuit configured to sustain oscillations of the microelectromechanical device; a compensation terminal capacitively coupled to the movable structure and configured to apply a compensation signal to the movable structure; and a modulation terminal cooperating with the sustaining circuit to control an amplitude of the oscillations of the microelectromechanical device;
wherein the method comprises:
applying a modulation signal having a modulation frequency to the modulation terminal;
generating, in response to an output signal of the microelectromechanical oscillator, a read-out signal indicative of a frequency variation of the oscillations of the microelectromechanical device with respect to the working frequency;
demodulating, in a synchronous manner, the read-out signal using the modulation signal, so as to obtain an error signal indicative of a phase difference between the modulation signal and the read-out signal;
comparing the error signal with a reference signal; and
generating the compensation signal from the comparison.

14. The method according to claim 13, wherein the modulation signal is a sinusoidal signal and further comprising limiting, with a limitation circuit stage of the sustaining circuit, the amplitude of the oscillations and wherein the modulation terminal is connected to the limitation circuit stage.

15. The method according to claim 13, wherein the read-out signal is proportional to the frequency variation of the oscillations of the microelectromechanical device with respect to the working frequency, and wherein generating the read-out signal comprises sensing the output signal of the microelectromechanical oscillator using a phase-locked loop circuit.

16. The method according to claim 13, wherein the compensation terminal is connected to a compensation electrode of the microelectromechanical device, the compensation electrode being capacitively coupled to electrodes of the movable structure.

17. The method according to claim 16, wherein the electrodes of the movable structure are in a parallel plate configuration.
